(19) United States
(12) Patent Application Publication
(10) Pub. No.: US 2026/0006849 A1
(43) Pub. Date: Jan. 1, 2026

(54) THIN FILM TRANSISTOR AND ELECTRONIC DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP); Emi KAWASHIMA, Tokyo (JP); Yuki TSURUMA, Tokyo (JP); Daichi SASAKI, Tokyo (JP)

(73) Assignees: Japan Display Inc., Tokyo (JP); IDEMITSU KOSAN CO., LTD., Tokyo (JP)

(21) Appl. No.: 19/319,774

(22) Filed: Sep. 5, 2025

Related U.S. Application Data
(63) Continuation of application No. PCT/JP2024/009575, filed on Mar. 12, 2024.

(30) Foreign Application Priority Data
Mar. 17, 2023 (JP) 2023-043065

(51) Int. Cl. H10D 30/67; H10D 30/01

(52) U.S. Cl. CPC H10D 30/6755; H10D 30/031; H10D 30/6723; H10D 30/6757

(57) ABSTRACT

A thin film transistor includes a metal oxide layer provided over a substrate, an oxide semiconductor layer including a plurality of crystal grains and provided in contact with the metal oxide layer, a gate electrode provided over the oxide semiconductor layer, and a gate insulating layer provided between the oxide semiconductor layer and the gate electrode. When a crystal orientation at each of a plurality of measurement points of the oxide semiconductor layer is obtained based on an electron diffraction pattern obtained by transmitting an electron beam irradiated from a direction intersecting a thickness direction of the oxide semiconductor layer, an average KAM value calculated at the plurality of measurement points is greater than or equal to 0.6 degrees.

### CROSS-REFERENCE TO RELATED APPLICATIONS

This application is a Continuation of International Patent Application No. PCT/JP2024/009575, filed on Mar. 12, 2024, which claims the benefit of priority to Japanese Patent Application No. 2023-043065, filed on Mar. 17, 2023, the entire contents of each are incorporated herein by reference.

### FIELD

An embodiment of the present invention relates to a thin film transistor including an oxide semiconductor film having a polycrystalline structure (Poly-OS). Further, an embodiment of the present invention relates to an electronic device including the thin film transistor.

### BACKGROUND

In recent years, instead of a silicon semiconductor film using amorphous silicon, low-temperature polysilicon, and single-crystal silicon, a thin film transistor in which an oxide semiconductor film is used for a channel has been developed (for example, see Japanese laid-open patent publication Nos. 2021-141338, 2014-099601, 2021-153196, 2018-006730, 2016-184771, and 2021-108405). The thin film transistor including an oxide semiconductor film can be manufactured with a simple structure and low-temperature process, similar to a thin film transistor including an amorphous silicon film. Further, the thin film transistor including an oxide semiconductor film is known to have a higher field-effect mobility than the thin film transistor including an amorphous silicon film.

### SUMMARY

A thin film transistor according to an embodiment of the present invention includes a metal oxide layer provided over a substrate, an oxide semiconductor layer including a plurality of crystal grains and provided in contact with the metal oxide layer, a gate electrode provided over the oxide semiconductor layer, and a gate insulating layer provided between the oxide semiconductor layer and the gate electrode. When a crystal orientation at each of a plurality of measurement points of the oxide semiconductor layer is obtained based on an electron diffraction pattern obtained by transmitting an electron beam irradiated from a direction intersecting a thickness direction of the oxide semiconductor layer, an average KAM value calculated at the plurality of measurement points is greater than or equal to 0.6 degrees.

An electronic device according to an embodiment of the present invention includes the thin film transistor.

### BRIEF DESCRIPTION OF DRAWINGS

FIG. 1 is a schematic cross-sectional view showing a configuration of a thin film transistor according to an embodiment of the present invention.

FIG. 2 is a schematic plan view showing a configuration of a thin film transistor according to an embodiment of the present invention.

FIG. 3 is a schematic diagram illustrating a TEM-ED mapping method.

FIG. 4 is a flowchart showing a method for manufacturing a thin film transistor according to an embodiment of the present invention.

FIG. 5 is a schematic cross-sectional view showing a method for manufacturing a thin film transistor according to an embodiment of the present invention.

FIG. 6 is a schematic cross-sectional view showing a method for manufacturing a thin film transistor according to an embodiment of the present invention.

FIG. 7 is a schematic cross-sectional view showing a method for manufacturing a thin film transistor according to an embodiment of the present invention.

FIG. 8 is a schematic cross-sectional view showing a method for manufacturing a thin film transistor according to an embodiment of the present invention.

FIG. 9 is a schematic cross-sectional view showing a method for manufacturing a thin film transistor according to an embodiment of the present invention.

FIG. 10 is a schematic cross-sectional view showing a method for manufacturing a thin film transistor according to an embodiment of the present invention.

FIG. 11 is a schematic cross-sectional view showing a method for manufacturing a thin film transistor according to an embodiment of the present invention.

FIG. 12 is a schematic cross-sectional view showing a method for manufacturing a thin film transistor according to an embodiment of the present invention.

FIG. 13 is a schematic diagram showing an electronic device according to an embodiment of the present invention.

FIG. 14 is an inverse pole figure of an oxide semiconductor layer (Poly-OS film) of an example sample.

FIG. 15 is an IPF map of an oxide semiconductor layer (Poly-OS film) of an example sample.

FIG. 16 is a KAM map of an oxide semiconductor layer (Poly-OS film) of an example sample.

FIG. 17 is a graph showing a distribution of KAM values of oxide semiconductor layers (Poly-OS films) of example samples.

FIG. 18 is a graph showing a depth average KAM value in oxide semiconductor layers (Poly-OS films) of example samples.

### DESCRIPTION OF EMBODIMENTS

The field effect mobility of a thin film transistor including a conventional oxide semiconductor film is not so high even when a crystalline oxide semiconductor film is used in the thin film transistor. Therefore, it has been desired to improve the crystal structure of the oxide semiconductor film used in the thin film transistor and thereby improve the field effect mobility of the thin film transistor.

In view of the above problems, an embodiment of the present invention can provide a thin film transistor including an oxide semiconductor film having a novel crystal structure. Further, an embodiment of the present invention can provide an electronic device including the thin film transistor.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a thin film transistor and a pixel electrode do not overlap in a plan view when expressed as “a pixel electrode over a thin film transistor.” On the other hand, the expression “a pixel electrode vertically over a thin film transistor” means a positional relationship in which the thin film transistor and the pixel electrode overlap in a plan view. In addition, a plan view refers to viewing from a direction perpendicular to a surface of the substrate.

In the present specification and the like, the terms “film” and “layer” can be optionally interchanged with one another.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification and the like, the expression “a includes A, B, or C,” “a includes any of A, B, or C,” or “a includes one selected from a group consisting of A, B and C,” and the like does not exclude the case where a includes a plurality of combinations of A to C unless otherwise specified. Further, these expressions do not exclude the case where a includes other components.

In addition, the following embodiments can be combined with each other as long as there is no technical contradiction.

### First Embodiment

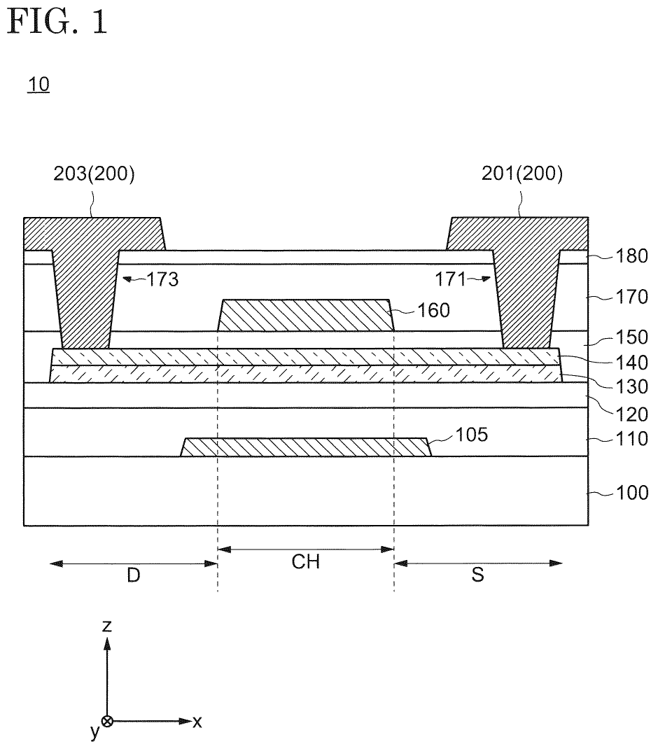

A thin film transistor 10 according to an embodiment of the present invention is described with reference to FIGS. 1 to 12. For example, the thin film transistor 10 may be used in an integrated circuit (IC) such as a micro-processing unit (MPU) or a memory circuit in addition to a transistor used in a display device.

### [1. Configuration of Thin Film Transistor 10]

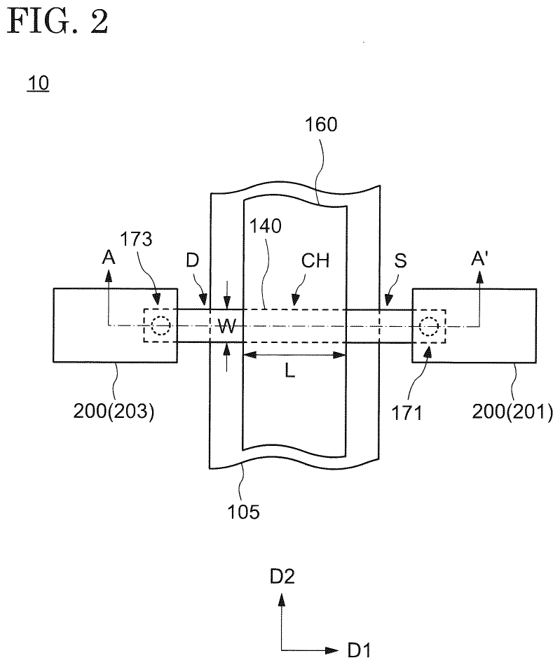

A configuration of a thin film transistor 10 according to an embodiment of the present invention is described with reference to FIGS. 1 and 2. FIG. 1 is a schematic cross-sectional view showing the configuration of the thin film transistor 10 according to an embodiment of the present invention. FIG. 2 is a schematic plan view showing the configuration of the thin film transistor 10 according to an embodiment of the present invention. Specifically, FIG. 1 is a cross-sectional view cut along the line A-A′ in FIG. 2.

As shown in FIG. 1, the thin film transistor 10 includes a substrate 100, a light shielding layer 105, a first insulating layer 110, a second insulating layer 120, a metal oxide layer 130, an oxide semiconductor layer 140, a gate insulating layer 150, a gate electrode 160, a third insulating layer 170, a fourth insulating layer 180, a source electrode 201, and a drain electrode 203. The light shielding layer 105 is provided on the substrate 100. The first insulating layer 110 is provided on the substrate 100 so as to cover an upper surface and an edge surface of the light shielding layer 105. The second insulating layer 120 is provided on the first insulating layer 110. The metal oxide layer 130 is provided on the second insulating layer 120. The oxide semiconductor layer 140 is provided on the metal oxide layer 130. The oxide semiconductor layer 140 is in contact with the metal oxide layer 130. The gate insulating layer 150 is provided on the second insulating layer 120 so as to cover an upper surface and an edge surface of the oxide semiconductor layer 140 and an edge surface of the metal oxide layer 130. The gate electrode 160 is provided on the gate insulating layer 150 so as to overlap the oxide semiconductor layer 140. The third insulating layer 170 is provided on the gate insulating layer 150 so as to cover an upper surface and an edge surface of the gate electrode 160. The fourth insulating layer 180 is provided on the third insulating layer 170. The gate insulating layer 150, the third insulating layer 170, and the fourth insulating layer 180 are provided with opening portions 171 and 173 through which a part of the upper surface of the oxide semiconductor layer 140 is exposed. The source electrode 201 is provided on the fourth insulating layer 180 and inside the opening portion 171, and is in contact with the oxide semiconductor layer 140. Similarly, the drain electrode 203 is provided on the fourth insulating layer 180 and inside the opening portion 173, and is in contact with the oxide semiconductor layer 140. In the following description, when the source electrode 201 and the drain electrode 203 are not particularly distinguished from each other, they may be collectively referred to as a source-drain electrode 200.

The oxide semiconductor layer 140 is divided into a source region S, a drain region D, and a channel region CH based on the gate electrode 160. That is, the oxide semiconductor layer includes the channel region CH which overlaps the gate electrode 160 and the source region S and the drain region D which do not overlap the gate electrode 160. In a thickness direction of the oxide semiconductor layer 140, an edge portion of the channel region CH is substantially aligned with an edge portion of the gate electrode 160. The channel region CH has properties of a semiconductor. Each of the source region S and the drain region D has properties of a conductor. Therefore, the electrical conductivities of the source region S and the drain region D are larger than the electrical conductivity of the channel region CH. The source electrode 201 and the drain electrode 203 are in contact with the source region S and the drain region D, respectively, and are electrically connected to the oxide semiconductor layer 140. Further, the oxide semiconductor layer 140 may have a single layer structure or a laminated structure.

As shown in FIG. 2, each of the light shielding layer 105 and the gate electrode 160 has a predetermined width in a direction D1 and extends in a direction D2 orthogonal to the direction D1. A width of the light shielding layer 105 is greater than a width of the gate electrode 160 in the direction D1. The channel region CH completely overlaps the light shielding layer 105. In the semiconductor device 10, the direction D1 corresponds to the direction in which a current flows from the source electrode 201 to the drain electrode 203 through the oxide semiconductor layer 140. Therefore, a length of the channel region CH in the direction D1 is a channel length L, and a width of the channel region CH in the direction D2 is a channel width W.

The substrate 100 can support each layer in the thin film transistor 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

The light shielding layer 105 can reflect or absorb external light. As described above, since the light shielding layer 105 has a larger area than the channel region CH of the oxide semiconductor layer 140, the light shielding layer 105 can block external light entering the channel region CH. For example, aluminum (Al), copper (Cu), titanium (Ti), molybdenum (Mo), tungsten (W), or alloys or compounds thereof can be used for the light shielding layer 105. Further, the light shielding layer 105 may not necessarily include a metal when conductivity of the light shielding layer 105 is not required. For example, a black matrix made of black resin can be used for the light shielding layer 105. Furthermore, the light shielding layer 105 may have a single layer structure or a laminated structure. For example, the light shielding layer 105 may have a laminated structure of a red color filter, a green color filter, and a blue color filter.

The first insulating layer 110, the second insulating layer 120, the third insulating layer 170, and the fourth insulating layer 180 can prevent impurities from diffusing into the oxide semiconductor layer 140. Specifically, the first insulating layer 110 and the second insulating layer 120 can prevent the diffusion of impurities contained in the substrate 100, and the third insulating layer 170 and the fourth insulating layer 180 can prevent the diffusion of impurities (for example, water) entering from the outside. For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) and the like are used for each of the first insulating layer 110, the second insulating layer 120, the third insulating layer 170, and the fourth insulating layer 180. Here, silicon oxynitride (SiOₓN_{y}) and aluminum oxynitride (AlOₓN_{y}) are a silicon compound and an aluminum compound, respectively, that contain a smaller proportion (x>y) of nitrogen (N) than oxygen (O). Silicon nitride oxide (SiNₓO_{y}) and aluminum nitride oxide (AlNₓO_{y}) are a silicon compound and an aluminum compound, respectively, that contain a smaller proportion (x>y) of oxygen than nitrogen. Further, each of the first insulating layer 110, the second insulating layer 120, the third insulating layer 170, and the fourth insulating layer 180 may have a single layer structure or a laminated structure.

Further, each of the first insulating layer 110, the second insulating layer 120, the third insulating layer 170, and the fourth insulating layer 180 may have a planarization function or a function of releasing oxygen by performing a heat treatment. For example, when the second insulating layer 120 has a function of releasing oxygen by performing a heat treatment, oxygen is released from the second insulating layer 120 by the heat treatment performed in the manufacturing process of the thin film transistor 10, and the released oxygen can be supplied to the oxide semiconductor layer 140.

The gate electrode 160, the source electrode 201, and the drain electrode 203 are conductive. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or alloys or compounds thereof can be used for each of the gate electrode 160, the source electrode 201, and the drain electrode 203. Each of the gate electrode 160, the source electrode 201, and the drain electrode 203 may have a single layer structure or a laminated structure.

The gate insulating layer 150 includes an oxide having insulating properties. Specifically, silicon oxide (SiOₓ), silicon oxynitride (SiOₓN_{y}), aluminum oxide (AlOₓ), aluminum oxynitride (AlOₓN_{y}), or the like is used for the gate insulating layer 150. The gate insulating layer 150 preferably has a composition close to the stoichiometric ratio. Further, the gate insulating layer 150 preferably has few defects. For example, an oxide in which few defects are observed when evaluated by electron spin resonance (ESR) may be used for the gate insulating layer 150.

The metal oxide layer 130 includes a metal oxide having insulating properties. Specifically, the metal oxide having a band gap greater than or equal to 4 eV and less than or equal to 10 eV is used as the metal oxide layer 130. Further, the metal oxide containing one or more metal elements selected from aluminum (Al), magnesium (Mg), calcium (Ca), scandium (Sc), gallium (Ga), germanium (Ge), strontium (Sr), nickel (Ni), tantalum (Ta), yttrium (Y), zirconium (Zr), barium (Ba), hafnium (Hf), cobalt (Co), and lanthanoid elements is used for the metal oxide layer 130, for example. In particular, it is preferable that the metal oxide containing aluminum (e.g., aluminum oxide, etc.) is used for the metal oxide layer 130. The metal oxide containing aluminum has high barrier properties against gases such as oxygen or hydrogen.

The metal oxide layer 130 can also function as a buffer layer for the oxide semiconductor layer 140. For example, when a heat treatment is performed on the oxide semiconductor layer 140 in contact with the metal oxide layer 130, the crystallinity of the oxide semiconductor layer 140 can be improved.

Next, an oxide semiconductor film having a novel crystal structure used for the oxide semiconductor layer 140 is described.

### [2. Configuration of Oxide Semiconductor Film]

### [2-1. Composition of Oxide Semiconductor Film]

The oxide semiconductor film contains indium (In) and at least one or more metal elements (M) other than indium. It is preferable that the composition ratio of the oxide semiconductor film has an atomic ratio of indium and at least one or more metal elements which satisfies Formula (1). In other words, it is preferable that the ratio of indium to all metal elements in the oxide semiconductor film is greater than or equal to 50%. When the ratio of indium in the oxide semiconductor film increases, the oxide semiconductor film having crystallinity can be formed. Further, it is preferable that a crystal structure of the oxide semiconductor film has a bixbyite structure. When the ratio of indium in the oxide semiconductor film increases, the oxide semiconductor film having a bixbyite structure can be formed.

$$0.01 < \frac{[ M ]}{[ In ] + [ M ]} < 0.5 \qquad ( 1 )$$

In addition, the metal element other than indium is not limited to one type of metal element. The metal element other than indium may include a plurality of types of metal elements.

Although details of a method for manufacturing the oxide semiconductor film are described later, the oxide semiconductor film can be formed by a sputtering method. The composition of the oxide semiconductor film formed by the sputtering method depends on the composition of the sputtering target. When the sputtering target has the above-described composition, the oxide semiconductor film without composition deviation of the metal elements can be formed by the sputtering method. Therefore, the composition of the metal elements (e.g., indium or other metal element) in the oxide semiconductor film may be equivalent to the composition of the metal elements in the sputtering target. For example, the composition of the metal elements in the oxide semiconductor film can be specified based on the composition of the metal elements in the sputtering target. In addition, oxygen contained in the oxide semiconductor film is not limited thereto because it changes depending on the process conditions of the sputtering method.

Further, the composition of the metal elements in the oxide semiconductor film can be specified by X-ray fluorescence analysis, electron probe micro analyzer (EPMA) analysis, or the like. Since the oxide semiconductor film has a polycrystalline structure, the composition of the oxide semiconductor film may be specified by X-ray diffraction (XRD). Specifically, the composition of the metal elements in the oxide semiconductor film can be specified based on the crystal structure and lattice constant of the oxide semiconductor film obtained by XRD.

### [2-2. Crystal Structure of Oxide Semiconductor Film]

The oxide semiconductor film has a polycrystalline structure including a plurality of crystal grains. Although details of the method for manufacturing the oxide semiconductor film are described later, the oxide semiconductor film having a novel polycrystalline structure different from a conventional oxide semiconductor film can be formed using a polycrystalline oxide semiconductor (Poly-OS) technique. Therefore, hereinafter, the oxide semiconductor film having a polycrystalline structure according to the present embodiment may be referred to as a Poly-OS film in order to distinguish it from the conventional oxide semiconductor film having a polycrystalline structure.

The crystal grain included in the oxide semiconductor layer 140 may be composed of a plurality of crystallites. Although the crystallite size is not limited to a particular size, the crystallite size is preferably greater than or equal to 1 nm, more preferably greater than or equal to 10 nm, and further preferably greater than or equal to 15 nm. The crystallite size can be obtained by an electron beam diffraction method, an XRD method, or the like.

Although the crystal structure of the Poly-OS film is not limited to a certain structure, it is preferable that the Poly-OS film has a bixbyite structure. The crystal structure of the Poly-OS film can be specified by an XRD method or an electron beam diffraction method.

In addition, a plurality of crystal grains may have one type of crystal structure, or may have a plurality of types of crystal structures in the Poly-OS film. When the Poly-OS film has the plurality of types of crystal structures, it is preferable that one of the plurality of types of crystal structures is a bixbyite structure.

The crystal structure of the Poly-OS film is different from that of the conventional oxide semiconductor film having a polycrystalline structure. Specifically, the present inventors found that the crystal grains included in the Poly-OS film have characteristics different from those of the crystal grains included in the conventional oxide semiconductor film. Such characteristics of the Poly-OS film can be measured by a transmission electron microscopy electron diffraction mapping (TEM-ED mapping) method. In addition, the TEM-ED mapping method may be referred to as an automated crystal orientation mapping transmission electron microscopy (ACOM-TEM) method. Hereinafter, measurement of an oxide semiconductor film by the TEM-ED mapping method is described.

### [2-2-1. TEM-ED Mapping Method]

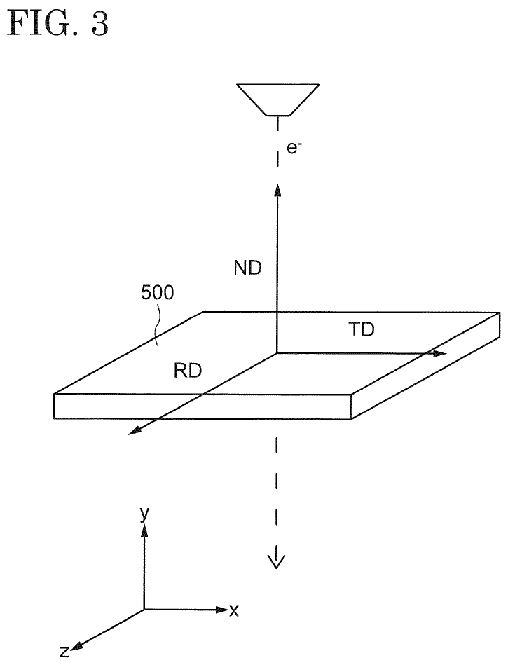

FIG. 3 is a schematic diagram illustrating the TEM-ED mapping method. The TEM-ED mapping method is an analysis method in which an electron beam is irradiated onto a measurement region of an object to be measured, an electron diffraction pattern observed after passing through the object to be measured is analyzed, and the crystal orientation in the measurement region of the object to be measured is measured. Since the electron diffraction pattern is continuously analyzed at a plurality of measurement points in the measurement region, information on the crystal orientation within or between crystal grains can be obtained. In the TEM-ED mapping method, a TEM sample 500 is used as the object to be measured. Therefore, the TEM-ED mapping method is capable of obtaining information on the crystal orientation in a smaller measurement region than the EBSD (Electron Back Scattered Diffraction) method using a SEM sample.

In addition, when the TEM-ED mapping method is applied to the oxide semiconductor layer 140 of the thin film transistor 10, a thin film sample including a cross section of the oxide semiconductor layer 140 of the thin film transistor 10 is used as the TEM sample 500. The TEM-ED mapping method is a measurement of a micro region using a TEM sample. Therefore, although the step interval of the measurement points at which the electron beam diffraction pattern is observed is, for example, greater than or equal to 1 nm, the step interval is not limited thereto. However, in the measurement of the crystal orientation, it is preferable to have a large number of measurement points in the thickness direction of the oxide semiconductor layer 140. For example, the step interval is less than or equal to ⅕, preferably less than or equal to 1/10, and more preferably less than or equal to 1/30 of the thickness of the oxide semiconductor layer.

In the TEM-ED mapping method, a coordinate system based on the TEM sample 500 (ND (Normal Direction), TD (Transverse Direction), and RD (Reference Direction)) is used, as shown in FIG. 3. In the coordinate system based on the TEM sample 500, the normal direction to the surface of the TEM sample 500 is the ND. The ND, TD, and RD are orthogonal to each other. The electron beam is irradiated to the TEM 500 from the ND.

FIG. 3 shows a coordinate system (x-axis, y-axis, and z-axis) based on the thin film transistor 10 (or the oxide semiconductor layer 140) as well as the coordinate system based on the TEM sample 500. In the coordinate system based on the thin film transistor 10, the thickness direction of the oxide semiconductor layer 140 is the z-axis. The x-axis, y-axis, and z-axis are orthogonal to each other. Therefore, the x-axis and y-axis are in-plane directions of the oxide semiconductor layer 140.

Accordingly, the ND, the TD, and the RD in the TEM-ED mapping method correspond to the y-axis, the x-axis, and the z-axis of the thin film transistor 10, respectively.

### [2-2-2. Inverse Pole Figure]

An inverse pole figure (IPF) is an image illustrating crystal orientations in a specific direction of the coordinate system based on the TEM sample 500. In the inverse pole figure, the proportion of crystal orientations in each direction of the coordinate system of the TEM sample 500 is shown according to a predetermined index. In general, the proportion of crystal orientations in a specific direction is color-coded according to a color key.

### [2-2-3. IPF Map]

An IPF map is an image in which the crystal orientation in a specific direction of the coordinate system based on the TEM sample 500 is illustrated as a distribution of crystal orientations on the surface of the TEM sample 500. In the IPF map, the crystal orientations at the plurality of measurement points are classified according to a predetermined index indicating the crystal orientation in each direction of the coordinate system of the TEM sample 500. In general, the crystal orientations are color-coded according to a color key.

### [2-2-4. Crystal Grain]

A crystal grain is a crystalline region surrounded by a grain boundary. Since the TEM-ED mapping method obtains information on the crystal orientation, the grain boundary can be defined based on the crystal orientations. In general, when the crystal orientation difference between two adjacent measurement points exceeds 5 degrees, it is defined that a grain boundary exists between them. Therefore, the above definition is also applied to the oxide semiconductor film.

The TEM-ED mapping method is a measurement in a small measurement region. Further, since a thin film sample having a cross section along the film thickness direction is used as a surface of the TEM sample 500, it is difficult to define the crystal grain size of the crystal grains spreading in the plane of the oxide semiconductor layer 140. Therefore, in the present embodiment, the length of the crystal grain obtained based on the cross section of the oxide semiconductor layer 140 in the measurement region is defined as the crystal grain length, instead of the crystal grain size. Specifically, the distance between two crystal grain boundaries obtained in the cross section of the oxide semiconductor layer 140 is defined as the crystal grain length. The crystal grain length defined in this manner may be calculated to be smaller than the crystal grain size. However, the crystal grain size of the crystal grain included in the Poly-OS film is significantly larger than the crystal grain size of the crystal grain included in a conventional oxide semiconductor film. That is, the crystal grain length of the Poly-OS film defined as the above description can be obtained as a value larger than the crystal grain size of the crystal grain included in the conventional oxide semiconductor film. Therefore, it is possible to compare the Poly-OS film with the conventional oxide semiconductor film by using the crystal grain length defined as the above description. In the Poly-OS film, the crystal grain length is greater than or equal to 100 nm, preferably greater than or equal to 300 nm, and more preferably greater than or equal to 500 nm. Although the upper limit of the crystal grain length is not particularly limited, the crystal grain length is less than or equal to 50 μm. The crystal grain length is preferably measured at the central portion of the thickness.

As described above, the crystal grain length of the crystal grain included in the Poly-OS film is large, and one crystal grain may form part of the upper surface and part of the lower surface of the Poly-OS film. In this case, although the crystal grain boundary between two adjacent crystal grains is formed from the upper surface to the lower surface (or from the lower surface to the upper surface), the grain boundary is not formed along the thickness direction, and the position of the upper surface and the position of the lower surface of the crystal grain boundary may be misaligned. In other words, two adjacent crystal grains with a crystal grain boundary interposed therebetween overlap each other in the thickness direction of the Poly-OS film. Further, the distance between the position of the upper surface and the position of the lower surface of the crystal grain boundary in the direction perpendicular to the thickness direction of the Poly-OS film, that is, the overlapping distance of two adjacent crystal grains is, for example, greater than or equal to 10 nm, preferably greater than or equal to 20 nm, and more preferably greater than or equal to 30 nm.

### [2-2-5. KAM Value]

A KAM (Kernel Average Misorientation) value is an average value of the crystal orientation difference between one measurement point in a crystal grain and all measurement points adjacent to the one measurement point. The crystal orientation difference between two adjacent measurement points with a grain boundary interposed therebetween is excluded from the calculation of the KAM value.

The KAM value is a value that represents the change in crystal orientation within one crystal grain. As described above, when the crystal orientation difference between one measurement point and another measurement point adjacent to the one measurement point exceeds 5 degrees, it is considered to be a grain boundary. Therefore, the range of the KAM value calculated based on adjacent measurement points within one crystal grain is greater than or equal to 0 degrees and less than or equal to 5 degrees. A large KAM value means that the local change in crystal orientations within the crystal grain is large, and the crystal grain is highly distorted.

The KAM value is calculated at each of the plurality of measurement points. Therefore, a distribution diagram of the KAM value in the crystal grain can be created. Further, an average value and a standard deviation of the KAM value can be calculated. The average KAM value is a value that represents one of the properties of the crystal grains included in the Poly-OS film. Since the Poly-OS film has a large change in crystal orientation and contains many crystal grains with a large distortion, the average KAM value of the Poly-OS film is larger than that of a conventional oxide semiconductor film having a polycrystalline structure. The average KAM value in the Poly-OS film is greater than or equal to 0.6 degrees, preferably greater than or equal to 0.7 degrees, and more preferably greater than or equal to 0.8 degrees. Similarly, the standard deviation of the KAM value is also a value that represents one of the properties of the crystal grains included in the Poly-OS film. In the Poly-OS film, the standard deviation of the KAM value is greater than or equal to 0.3 degrees, preferably greater than or equal to 0.35 degrees, and more preferably greater than or equal to 0.4 degrees.

Further, the average KAM value in the Poly-OS film increases as the step interval between the measurement points increases. This is due to the large change in crystal orientation within the crystal grain contained in the Poly-OS film, and the tendency for the average KAM value to increase with an increase in the step interval is one of the characteristics of the Poly-OS film.

In addition, the average KAM value described above is the total average KAM value (KAM_{AVE(total)}) calculated using the KAM values of all the measurement points in the measurement region. Unless otherwise specified in the present specification, the average KAM value refers to the total average KAM value (KAM_{AVE(total)}). On the other hand, it is also possible to calculate the average KAM value using some of the measurement points in the measurement region. For example, the thickness of the Poly-OS film can be divided, and the average KAM values of the measurement points included in the divided regions can be calculated. The average KAM values calculated using some of the measurement points is different from the total average KAM value (KAM_{AVE(total)}). The average KAM values calculated by dividing the thickness of the Poly-OS film depends on the distance (depth) of the thickness of the Poly-OS film. Therefore, in the present specification, the average value is sometimes referred to as the depth average KAM value (KAM_{AVE(depth)}) to be distinguished from the total average KAM value (KAM_{AVE(total)}).

As described above, since the crystal grain length of the Poly-OS film is large, the Poly-OS film may be formed of one crystal grain from the upper surface to the lower surface. In the Poly-OS film, the crystal orientation also changes significantly in the thickness direction of the Poly-OS film. Specifically, the depth average value (KAM_{AVE(depth)}) of the KAM value is different between the upper end portion and the lower end portion (which are near the interface, for example, within 3 nm from the interface) and the central portion (which is near a center, for example, within 5 nm located equidistant from the upper end portion and the lower end portion) of the Poly-OS film. The depth average value (KAM_{AVE(depth)}) of the KAM value at each of the upper end portion and the lower end portion of the Poly-OS film is greater than or equal to 0.6 degrees and less than 5.0 degrees, and preferably greater than or equal to 0.7 degrees and less than 5.0 degrees. On the other hand, the depth average KAM value (KAM_{AVE(depth)}) at the central portion of the Poly-OS film is less than 0.6 degrees. The difference in the depth average KAM value (KAM_{AVE(depth)}) between the upper end portion or the lower end portion and the central portion of the Poly-OS film is greater than or equal to 0.1 degrees, preferably greater than or equal to 0.15 degrees, and further preferably greater than or equal to 0.2 degrees.

The upper surface and the lower surface of the Poly-OS film may have unevenness. In this case, the number of measurement points at the upper end portion and the lower end portion is reduced, and the error in the depth average KAM values (KAM_{AVE(depth)}) at the upper end portion and the lower end portion is likely to be large. Therefore, the depth average KAM values (KAM_{AVE(depth)}) at the upper end portion and the lower end portion may be calculated by using a region in which the number of measurement points included in the divided region is greater than or equal to 90% of the number of measurement points in the central portion (or a region in which the number of measurement points is greater than or equal to 90% of the maximum number of measurement points) as an effective region. In an effective Poly-OS film including the effective region, the depth average KAM values (KAM_{AVE(depth)}) at the upper end portion and the lower end portion can be calculated without being affected by the unevenness formed on the upper surface and the lower surface.

As described above, the TEM-ED mapping method can obtain information about the crystal orientation in the crystal grain included in the Poly-OS film. For example, when the Poly-OS film has a bixbyite structure, the TEM-ED mapping method can observe that the Poly-OS film includes a crystal grain with a crystal orientation of <001>, <101>, or <111>.

Here, the crystal orientation <001> represents and its equivalents [100] and [010]. The crystal orientation <101> represents and its equivalents [110] and [011]. The crystal orientation <111> represents [111]. Further, in each orientation, “1” may be “−1” and is considered to be an axis equivalent to each orientation.

Further, crystal orientations include <hk0> (h≠k, h and k are natural numbers), <hhl> (h≠l, h and l are natural numbers), and <hkl> (h+k≠l, h, k, and l are natural numbers) other than <001>, <101>, and <111>.

The crystal grains in the Poly-OS film have a property whereby the crystal orientation changes significantly within the crystal grain. When the characteristics of the Poly-OS film are quantified by a TEM-ED method, the average KAM value of the Poly-OS film is greater than or equal to 0.6 degrees. In the case of the conventional oxide semiconductor film, when the change in the crystal orientation within the crystal grain is large, crystal dislocation is likely to occur, and the crystal grain size of the crystal grain is small. However, in the Poly-OS film, although the change in the crystal orientation within the crystal grain is large, the crystal grain length (or crystal grain size) of the crystal grain is large as described above. Such a characteristic of the Poly-OS film is completely different from that of the conventional oxide semiconductor film. As a result of trial and error, the inventors have found the Poly-OS film having a novel crystal structure. The Poly-OS film is less likely to receive the influence of crystal grain boundaries because it includes crystal grains with a large crystal grain length (or crystal grain size). Therefore, in the thin film transistor 10 including the Poly-OS film as the channel, the channel is less likely to receive the influence of grain boundaries, grain boundary scattering is suppressed, and field effect mobility is improved.

In addition, the crystal orientation of the crystal grain in the Poly-OS film is described in detail later along with examples.

Although the configuration of the thin film transistor 10 is described above, the thin film transistor 10 described above is a so-called top-gate transistor. The thin film transistor 10 can be modified in various ways. For example, when the light shielding layer 105 has conductivity, the thin film transistor 10 may have a structure in which the light shielding layer 105 functions as a gate electrode, and the first insulating layer 110 and the second insulating layer 120 function as gate insulating layers. In this case, the thin film transistor 10 is a so-called dual-gate transistor. Further, when the light shielding layer 105 has conductivity, the light shielding layer 105 may be a floating electrode and may be connected to the source electrode 201. Furthermore, the thin film transistor 10 may be a so-called bottom-gate transistor in which the light shielding layer 105 functions as a main gate electrode.

### [3. Method for Manufacturing Thin Film Transistor 10]

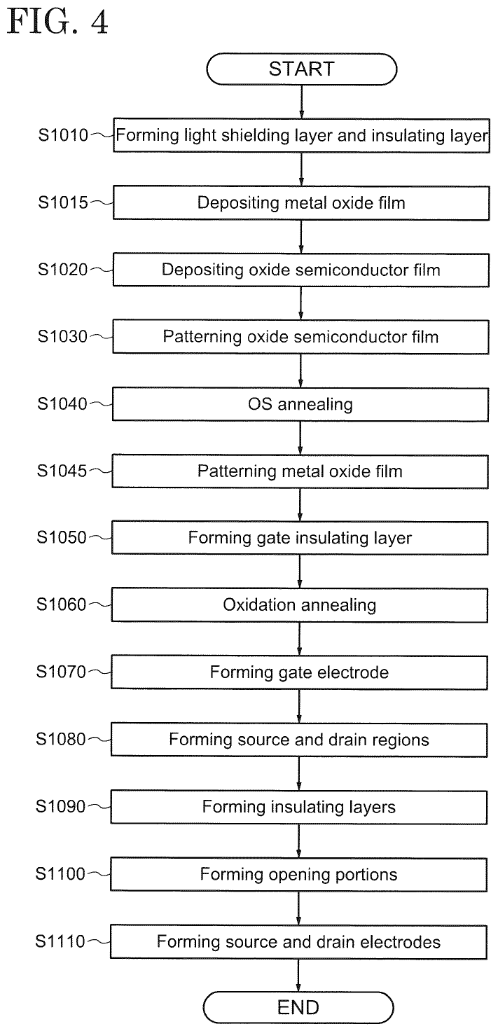

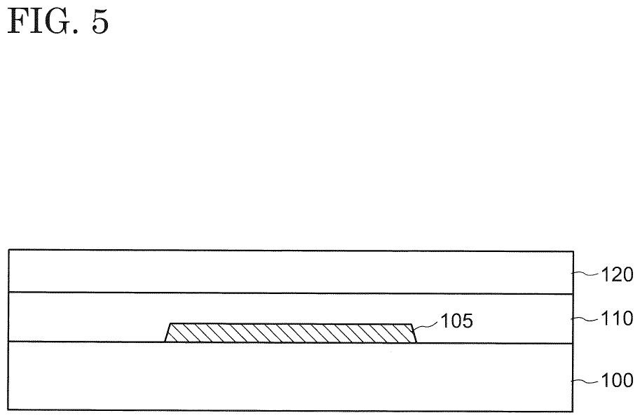

A method for manufacturing the thin film transistor 10 according to an embodiment of the present invention is described with reference to FIGS. 4 to 12. FIG. 4 is a flowchart showing the method for manufacturing the thin film transistor 10 according to an embodiment of the present invention. FIGS. 5 to 12 are schematic cross-sectional views showing the method of manufacturing the thin film transistor 10 according to an embodiment of the present invention.

As shown in FIG. 4, the method for manufacturing the thin film transistor 10 includes steps S1010 to S1110. In the following description, although the steps S1010 to S1110 are described in order, the order of the steps may be interchanged in the method for manufacturing the thin film transistor 10. Further, the method for manufacturing the thin film transistor 10 may include additional steps.

In step S1010, the light shielding layer 105 having a predetermined pattern is formed on the substrate 100. The patterning of the light shielding layer 105 is performed using a photolithography method. The first insulating layer 110 and the second insulating layer 120 are formed on the light shielding layer 105 (see FIG. 5). The first insulating layer 110 and the second insulating layer 120 are deposited using a CVD method. For example, silicon nitride and silicon oxide are deposited as the first insulating layer 110 and the second insulating layer 120, respectively. When silicon nitride is used for the first insulating layer 110, the first insulating layer 110 can block impurities that diffuse from the substrate 100 into the oxide semiconductor layer 140. When silicon oxide is used for the second insulating layer 120, the second insulating layer 120 can release oxygen by performing a heat treatment.

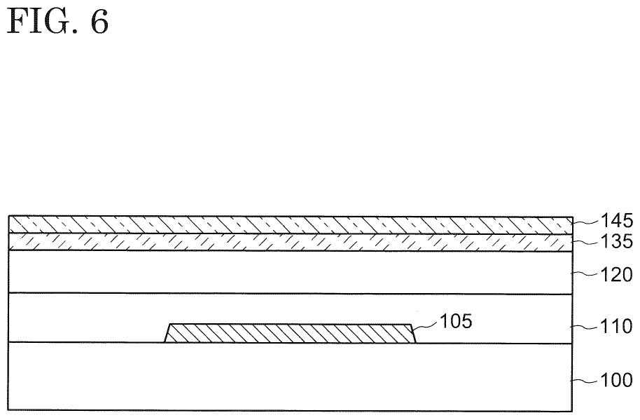

In step S1015, the metal oxide film 135 is deposited on the second insulating layer 120 (see FIG. 6). The metal oxide film 135 is deposited by a sputtering method. The thickness of the metal oxide film 135 is, for example, greater than or equal to 2 nm and less than or equal to 51 nm, preferably greater than or equal to 2 nm and less than or equal to 31 nm, more preferably greater than or equal to 2 nm and less than or equal to 21 nm, and particularly preferably greater than or equal to 2 nm and less than or equal to 11 nm.

In step S1020, an oxide semiconductor film 145 is deposited on the metal oxide film 135 (see FIG. 6). The oxide semiconductor film 145 is deposited by a sputtering method. The thickness of the oxide semiconductor film 145 is, for example, greater than or equal to 10 nm and less than or equal to 100 nm, preferably greater than or equal to 15 nm and less than or equal to 70 nm, and more preferably greater than or equal to 15 nm and less than or equal to 40 nm.

The oxide semiconductor film 145 in step S1020 is amorphous. In the Poly-OS technology, the oxide semiconductor film 145 after the deposition and before the heat treatment is preferably amorphous so that the oxide semiconductor layer 140 has a uniform polycrystalline structure in the substrate plane. Therefore, the deposition conditions of the oxide semiconductor film 145 are preferably conditions under which the oxide semiconductor film 145 immediately after the deposition is not crystallized as much as possible. When the oxide semiconductor film 145 is deposited by a sputtering method, the oxide semiconductor film 145 is deposited while controlling the temperature of the object to be deposited (the substrate 100 and the layers formed on the substrate 100) to less than or equal to 100° C., preferably less than or equal to 80° C., and more preferably less than or equal to 50° C. Further, the oxide semiconductor film 145 is deposited under the condition of a low oxygen partial pressure. The oxygen partial pressure is greater than or equal to 2% and less than or equal to 20%, preferably greater than or equal to 3% and less than or equal to 15%, and more preferably greater than or equal to 3% and less than 10%.

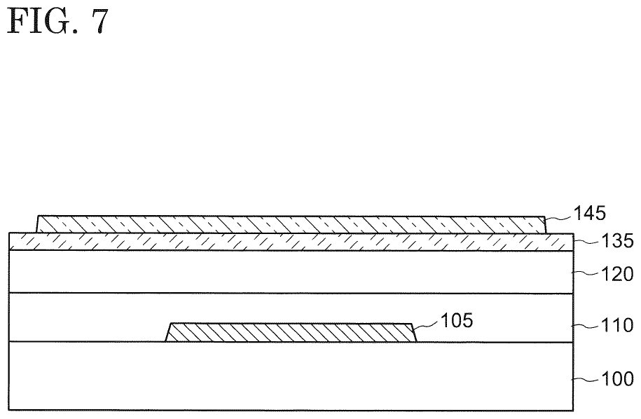

In step S1030, the oxide semiconductor film 145 is patterned (see FIG. 7). The patterning of the oxide semiconductor film 145 is performed using a photolithography method. Wet etching or dry etching may be used for the etching of the oxide semiconductor film 145. Wet etching can be performed using an acidic etchant. For example, oxalic acid, PAN, sulfuric acid, a hydrogen peroxide solution, hydrofluoric acid, or the like can be used for the etchant.

In step S1040, a heat treatment is performed on the oxide semiconductor film 145. Hereinafter, the heat treatment performed in step S1040 is referred to as “OS annealing.” In the OS annealing process, the oxide semiconductor film 145 is held at a predetermined reaching temperature for a predetermined time. The predetermined reaching temperature is higher than or equal to 300° C. and lower than or equal to 500° C., and preferably higher than or equal to 350° C. and lower than or equal to 450° C. Further, the predetermined time (holding time) at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure (that is, the oxide semiconductor layer 140 including the Poly-OS film) by the OS annealing process.

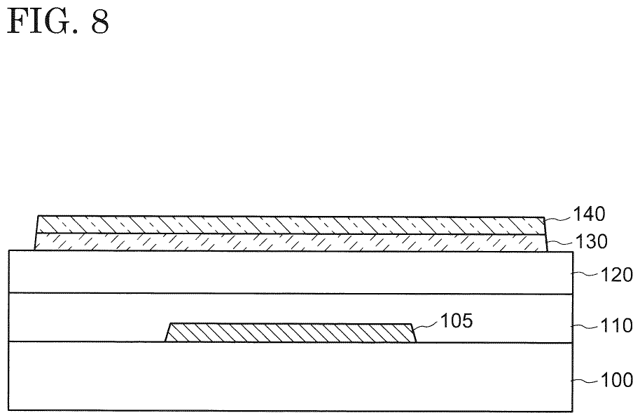

In step S1045, the metal oxide film 135 is patterned to form the metal oxide layer 130 (see FIG. 8). The metal oxide film 135 is etched using the oxide semiconductor layer 140 as a mask. When the patterned oxide semiconductor layer 140 is used as a mask, a photolithography process can be omitted. The metal oxide film 135 may be etched by wet etching or dry etching. For example, diluted hydrofluoric acid (DHF) is used in wet etching.

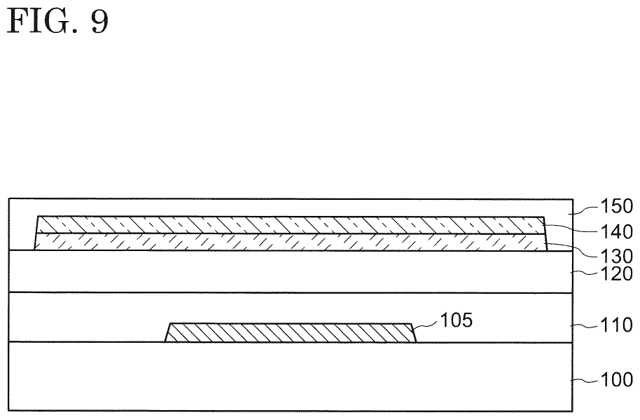

In step S1050, the gate insulating layer 150 is formed on the oxide semiconductor layer 140 (see FIG. 9). The gate insulating layer 150 is deposited using a CVD method. For example, silicon oxide is deposited for the gate insulating layer 150. In order to reduce defects in the gate insulating layer 150, the gate insulating layer 150 may be deposited at a deposition temperature higher than or equal to 350° C. The thickness of the gate insulating layer 150 is greater than or equal to 50 nm and less than or equal to 300 nm, preferably greater than or equal to 60 nm and less than or equal to 200 nm, and more preferably greater than or equal to 70 nm and less than or equal to 150 nm.

In step S1060, a heat treatment is performed on the oxide semiconductor layer 140. Hereinafter, the heat treatment performed in step S1060 is referred to as “oxidation annealing.” When the gate insulating layer 150 is formed on the oxide semiconductor layer 140, many oxygen vacancies are generated on the upper surface and side surfaces of the oxide semiconductor layer 140. When oxidation annealing is performed, oxygen is supplied from the second insulating layer 120 and the gate insulating layer 150 to the oxide semiconductor layer 140, and oxygen vacancies are repaired.

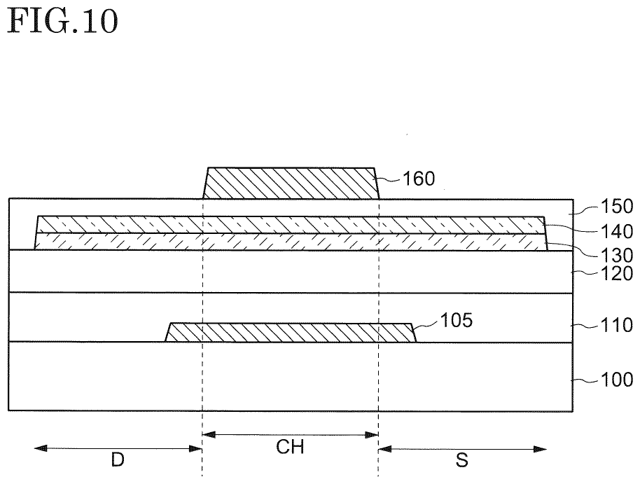

In step S1070, the gate electrode 160 having a predetermined pattern is formed on the gate insulating layer 150 (see FIG. 10). The gate electrode 160 is deposited by a sputtering method or an atomic layer deposition method, and patterning of the gate electrode 160 is performed using a photolithography method.

In step S1080, the source region S and the drain region D are formed in the oxide semiconductor layer 140 (see FIG. 10). The source region S and the drain region D are formed by ion implantation. Specifically, impurities are implanted into the oxide semiconductor layer 140 through the gate insulating layer 150 using the gate electrode 160 as a mask. For example, argon (Ar), phosphorus (P), boron (B), or the like is used as the implanted impurity. Oxygen deficiencies are generated by the ion implantation in the source region S and the drain region D that do not overlap the gate electrode 160, and hydrogen is trapped in the generated oxygen deficiencies. In this way, the resistance of the source region S and the drain region D is lowered. On the other hand, since no impurities are implanted in the channel region CH that overlaps the gate electrode 160, the resistance of the channel region CH is not lowered.

In addition, in the thin film transistor 10, since impurities are implanted into the oxide semiconductor layer 140 through the gate insulating layer 150, impurities such as argon (Ar), phosphorus (P), boron (B), or the like are included in the gate insulating layer 150.

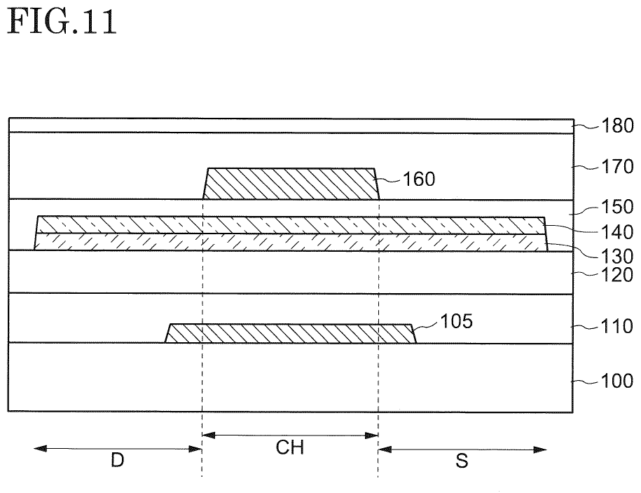

In step S1090, the third insulating layer 170 and the fourth insulating layer 180 are formed over the gate insulating layer 150 and the gate electrode 160 (see FIG. 11). The third insulating layer 170 and the fourth insulating layer 180 are deposited using a CVD method. For example, silicon oxide and silicon nitride are deposited for the third insulating layer 170 and the fourth insulating layer 180, respectively. The thickness of the third insulating layer 170 is greater than or equal to 50 nm and less than or equal to 500 nm. The thickness of the fourth insulating layer 180 is also greater than or equal to 50 nm and less than or equal to 500 nm.

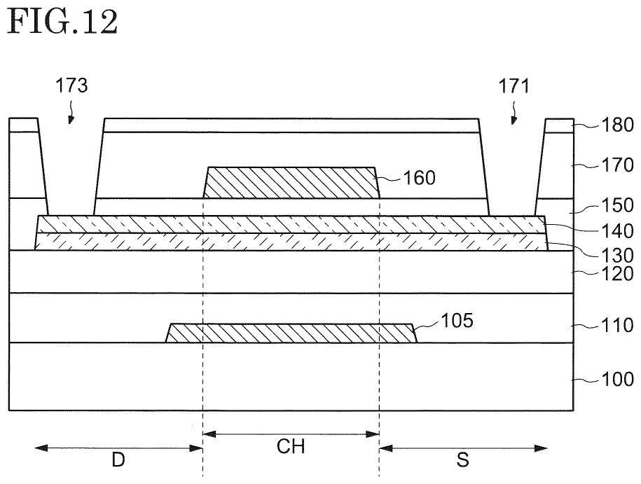

In step S1100, the opening portions 171 and 173 are formed in the gate insulating layer 150, the third insulating layer 170, and the fourth insulating layer 180 (see FIG. 12). The source region S and the drain region D of the oxide semiconductor layer 140 are exposed by the formation of the opening portions 171 and 173.

In step S1110, the source electrode 201 is formed on the fourth insulating layer 180 and inside the opening portion 171, and the drain electrode 203 is formed on the fourth insulating layer 180 and inside the opening portion 173. The source electrode 201 and the drain electrode 203 are formed as the same layer. Specifically, the source electrode 201 and the drain electrode 203 are formed by patterning one deposited conductive film. The thin film transistor 10 shown in FIG. 1 is manufactured through the above steps.

Although the method for manufacturing the thin film transistor 10 is described above, the method for manufacturing the thin film transistor 10 is not limited thereto.

In the thin film transistor 10 according to the present embodiment, the oxide semiconductor layer 140 includes the Poly-OS film having a novel crystal structure. The Poly-OS film includes the crystal grain with a large change in crystal orientation and a large crystal grain length (or crystal grain size). Therefore, in the thin film transistor 10 including the Poly-OS film as a channel, the channel as a whole is less likely to receive the influence of crystal grain boundaries. Further, it is considered that the crystal orientation in the crystal grains changes so as to improve the lattice matching at the crystal grain boundaries, and as a result, crystal grain boundaries with fewer defects are generated. For these reasons, in the thin film transistor 10 including the Poly-OS film as a channel, grain boundary scattering is suppressed and field effect mobility is improved.

### Second Embodiment

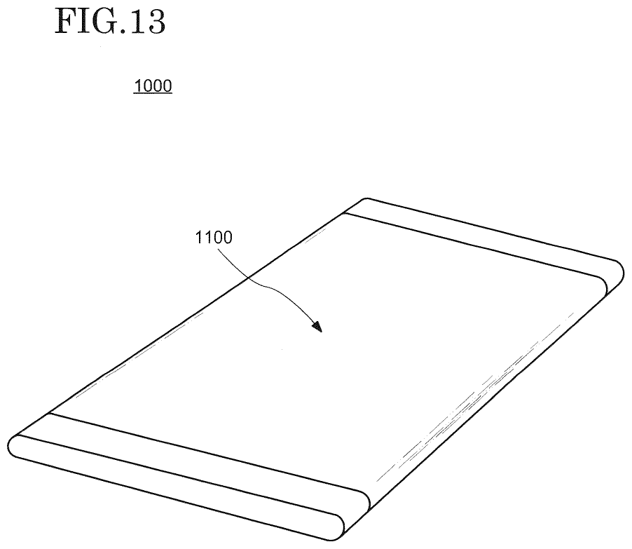

An electronic device according to an embodiment of the present embodiment is described with reference to FIG. 13.

FIG. 13 is a schematic diagram showing an electronic device 1000 according to an embodiment of the present embodiment. Specifically, FIG. 13 shows a smartphone, which is an example of the electronic device 1000. The electronic device 1000 includes a display device 1100 with curved sides. The display device 1100 includes a plurality of pixels for displaying an image. The plurality of pixels is controlled by a pixel circuit, a drive circuit, and the like. The pixel circuit and the drive circuit include the thin film transistor 10 described in the First Embodiment. Since the thin film transistor 10 has high field effect mobility, the responsiveness of the pixel circuit and the drive circuit can be improved, and as a result, the performance of the electronic device 1000 can be improved.

In addition, the electronic device 1000 according to the present embodiment is not limited to a smartphone. For example, the electronic device 1000 also includes an electronic device having a display device, such as a watch, a tablet, a notebook computer, a car navigation system, or a television. Further, the thin film transistor 10 described in the First Embodiment can be applied to any electronic device, regardless of whether or not the electronic device has a display device.

### EXAMPLES

An oxide semiconductor layer (specifically, a Poly-OS film) is described in further detail based on the manufactured thin film transistor.

### [1. Fabrication of Thin Film Transistor]

A thin film transistor was fabricated using the manufacturing method described in the First Embodiment. In the sputtering process for depositing the oxide semiconductor layer, a sputtering target in which indium makes up 70% in atomic ratio to all metal elements contained in the sintered body was used to deposit an oxide semiconductor layer with a thickness of 30 nm. The oxygen partial pressure during film deposition was 5%, and the substrate temperature was controlled to be less than or equal to 100° C. In the OS annealing process, the reaching temperature was controlled between 350° C. and 450° C. in an air atmosphere, and the reaching temperature was held for 60 minutes. The chemical composition of the oxide semiconductor layer after the OS annealing process was the same as that of the sputtering target.

### [2. Crystal Orientation Analysis Using TEM-ED Mapping Method]

A TEM sample (hereinafter referred to as an “example sample”) was prepared by sampling a cross section of a region including an oxide semiconductor layer of a thin film transistor by FIB processing, and a crystal orientation analysis of a Poly-OS film included in the oxide semiconductor layer was performed by TEM-ED mapping. The measurement conditions for the TEM-ED mapping are shown in Table 1. An ASTAR manufactured by NanoMegas Corporation was used for the analysis of the crystal orientation. A powder diffraction file (PDF) of 04-024-4517 of IC DD (International Centre for Diffraction Date) was used for orientation of the crystal structure.

TABLE 1

| Device | JEM-ARM200F manufactured by JEOL Ltd. | |
|---|---|---|
| Acceleration Voltage | 200 | kV |
| Measurement Region | 60 nm × 1200 nm | |
| Step Interval | 1 | nm |

### [2-1. Inverse Pole Figure]

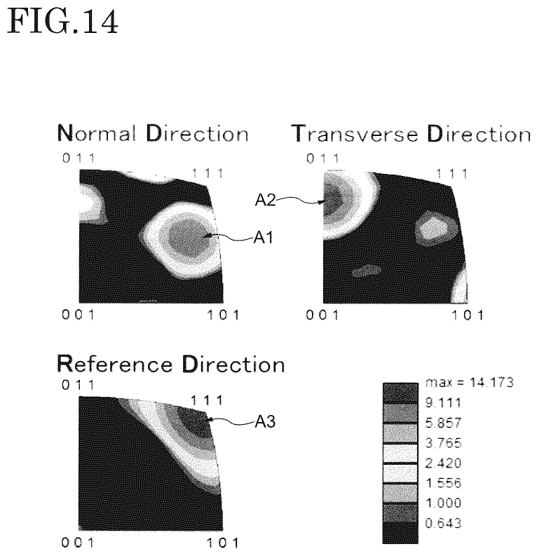

FIG. 14 is an inverse pole figure of the oxide semiconductor layer (Poly-OS film) of the example sample. FIG. 14 shows inverse pole figures for ND, TD, and RD. In the inverse pole figures for ND, TD, and RD, the proportion of the crystal orientation increases according to the value of the index shown in FIG. 14 (for example, the index may be a color key, and the proportion of the crystal orientation increases as the color changes from blue to red (the wavelength of visible light increases)). There are regions (regions A1, A2, and A3) having large values in all of ND, TD, and RD, and it was found that there are specific crystal orientations with a large proportion. For example, in RD corresponding to the thickness direction of the oxide semiconductor layer, the proportion of the crystal orientation <111> is larger than that of the crystal orientation <001> and the crystal orientation <101>.

### [2-2. IPF Map]

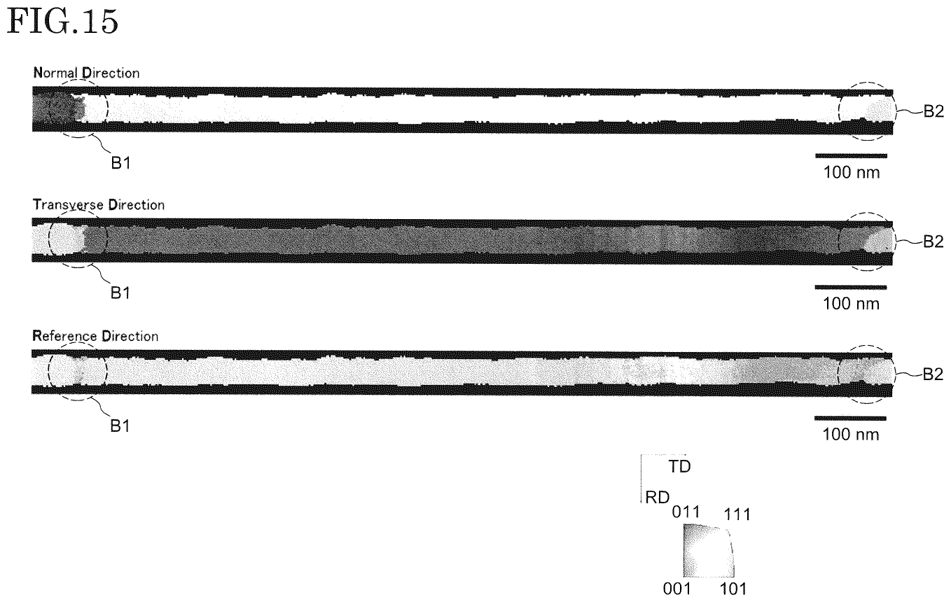

FIG. 15 is an IPF map of the oxide semiconductor layer (Poly-OS film) of the example sample. FIG. 15 shows IPF maps for ND, TD, and RD. In FIG. 15, the crystal orientation <001>, the crystal orientation <101>, the crystal orientation <111>, and the crystal orientation <011> are classified according to the indices in the figure.

In regions B1 and B2 shown in FIG. 15, the crystal orientation changes significantly and discontinuously. The discontinuous change in the crystal orientation corresponds to a grain boundary, and it is confirmed that a grain boundary forms from the upper surface to the lower surface (or from the lower surface to the upper surface) of the oxide semiconductor layer in the regions B1 and B2. The grain length of one crystal grain between the grain boundaries defined by the region B1 and B2 is 1080 nm. Further, one crystal grain formed a part of the upper surface and a part of the lower surface of the oxide semiconductor layer. That is, the grain length is greater than or equal to 10 times the thickness of the oxide semiconductor layer.

The crystal orientations within the grains in the IPF maps corresponded to the proportions of crystal orientations in the inverse pole figures described above. For example, the main crystal orientation of the grain in the RD is the crystal orientation <111>.

The grain boundary in the region B2 is not formed along the thickness direction of the oxide semiconductor layer, and is significantly shifted from the thickness direction of the oxide semiconductor layer. That is, two adjacent crystal grains sandwiching the grain boundary in the region B2 interposed therebetween overlap each other in the thickness direction of the oxide semiconductor layer. The overlap distance between the two adjacent crystal grains in the direction perpendicular to the thickness direction of the oxide semiconductor layer is 34 nm.

In addition, although not shown in the figures, crystal grain boundaries can also be confirmed in the TEM image in the regions B1 and B2.

### [2-3. KAM Value]

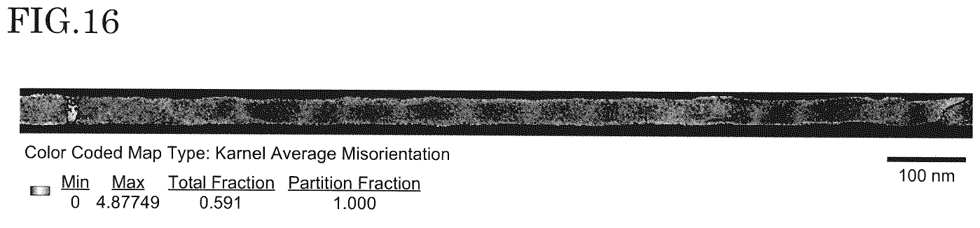

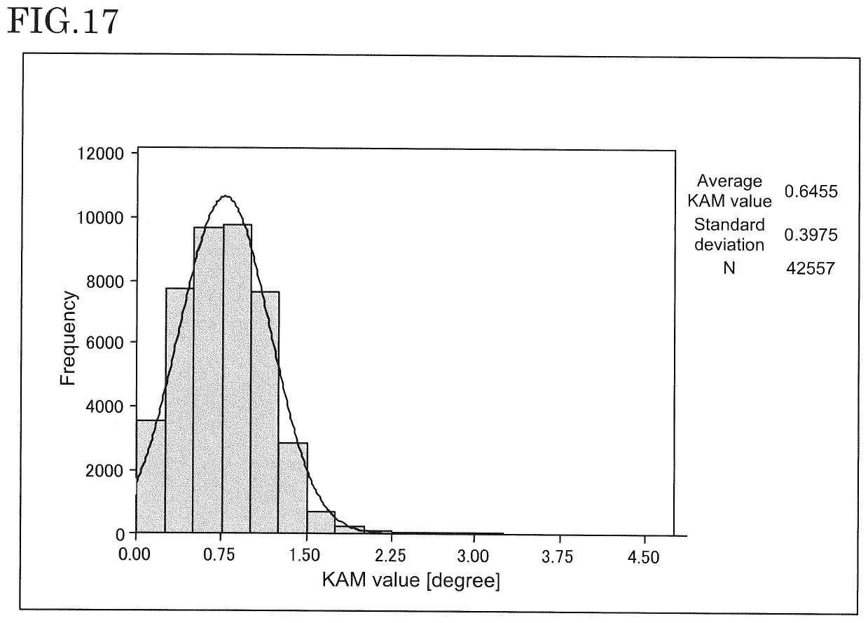

FIG. 16 is a KAM map of the oxide semiconductor layer (Poly-OS film) of the example sample. Specifically, in FIG. 16, the KAM values of the measurement points in the measurement region are classified according to the values of the indices shown in the figure (for example, the indices may be a color key, and the KAM value increases from 0 degrees to 5 degrees as the color changes from blue to red (the wavelength of visible light increases)). In addition, when the crystal orientation difference between two adjacent measurement points exceeds 5 degrees, it is regarded as a grain boundary, and therefore the upper limit of the KAM value is 5 degrees. FIG. 17 is a graph showing the distribution of the KAM values of the oxide semiconductor layer (Poly-OS film) of the example sample.

As shown in FIG. 16, the oxide semiconductor layer has not only a region having a KAM value near 0 degrees (corresponding to the region shown in blue in the color key, hereinafter, for convenience of explanation, it is referred to as a “blue region”), but also a region having a KAM value other than near 0 degrees (corresponding to the region shown in green in the color key, hereinafter, for convenience of explanation, it is referred to as a “green region”). As an overall tendency, the blue region spread in the central portion of the oxide semiconductor layer, and the green region spread near the surface (near the upper end portion and the lower end portion) of the oxide semiconductor layer. As can be seen from FIG. 17, it can be confirmed that there are not only measurement points having a KAM value near 0 degrees, but also many measurement points having a KAM value other than 0 degrees. The total average KAM value (KAM_{AVE(total)}) calculated using the KAM values of all the measurement points is 0.646 degrees. Further, the standard deviation (o) of the KAM value is 0.396 degrees. When the step interval was 2 nm, the total average KAM values (KAM_{AVE(total)}) is 0.670 degrees. That is, as the step interval increases, the total average KAM values (KAM_{AVE(total)}) increases.

Although the TEM-ED mapping method is a measurement in a microscopic region, the total average value and standard deviation of the KAM value are large even in such a microscopic region in the case of the Poly-OS film. This means that there is a large change in crystal orientation within the crystal grain of the Poly-OS film. Although the crystal grain in the Poly-OS film has a large crystal grain length (or crystal grain size), there is a large local change in crystal orientation. This is one of the characteristics of the Poly-OS film that is not observed in the conventional oxide semiconductor film having a polycrystalline structure.

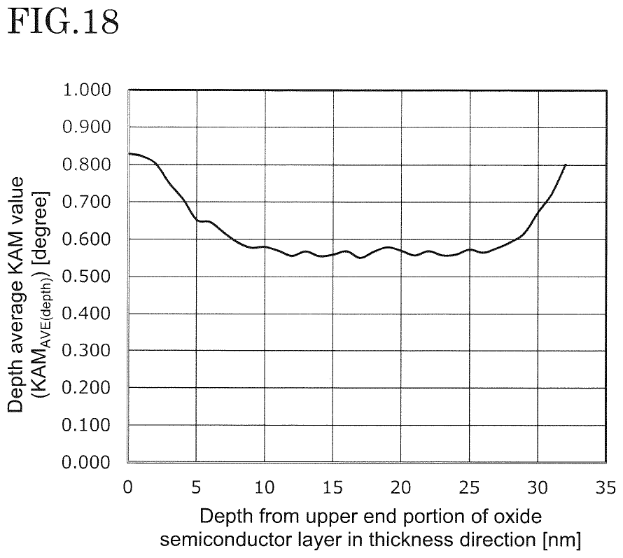

FIG. 18 is a graph showing a depth average KAM value in the oxide semiconductor layer (Poly-OS film) of the example sample. As described above, a difference is observed in the distribution of the KAM value between the central portion of the oxide semiconductor layer and the vicinity of the surface (the vicinity of the upper end portion and the lower end portion). Therefore, the KAM values of the measurement points are collected for each distance from the interface between the gate insulating layer and the oxide semiconductor layer (the depth of the oxide semiconductor layer), and the depth average KAM value (KAM_{AVE(depth)}) is calculated, which is the average value of the collected measurement points. The depth average KAM value (KAM_{AVE(depth)}) is the average KAM value of some measurement points divided according to the depth of the oxide semiconductor layer. In addition, a region in which the number of measurement points included in the divided region is greater than or equal to 90% of the number of measurement points in the central portion is set as a valid region in order to exclude the influence of the unevenness of the surface of the oxide semiconductor layer, and the depth average KAM value (KAM_{AVE(depth)}) of the oxide semiconductor layer is calculated. In the graph shown in FIG. 18, the depth average KAM value (KAM_{AVE(depth)}) is plotted against the depth in the thickness direction of the oxide semiconductor layer.

As shown in FIG. 18, the depth average KAM value (KAM_{AVE(depth)}) is larger at the upper end portion near the interface between the oxide semiconductor layer and the gate insulating layer and at the lower end portion near the interface between the oxide semiconductor layer and the metal oxide layer than at the central portion of the oxide semiconductor layer. The average depth KAM values (KAM_{AVE(depth)}) at the central portion (depth 15 nm), upper end portion (depth 0 nm), and lower end portion (depth 32 nm) are 0.554 degrees, 0.828 degrees, and 0.802 degrees, respectively. The difference in the average depth KAM values (KAM_{AVE(depth)}) between the upper end portion and the central portion, and the difference between the lower end portion and the central portion are greater than or equal to 0.2 degrees.

The above results indicate that the change in crystal orientation is large near the interface of the oxide semiconductor layer. In the Poly-OS film, the change in local crystal orientation is large even in the thickness direction. In the conventional oxide semiconductor film having a polycrystalline structure, since the crystal grain length (or crystal grain size) is small so that strain in the crystal grain is relaxed, it is difficult to form the oxide semiconductor film from the upper surface to the lower surface with one crystal grain. On the other hand, in the Poly-OS film, it is possible to form the oxide semiconductor film from the upper surface to the lower surface with one crystal grain that has a large change in crystal orientation. This is one of the characteristics of the Poly-OS film that is not observed in the conventional oxide semiconductor film having a polycrystalline structure.

### [3. Electrical Characteristics]

The electrical characteristics of the fabricated thin film transistor were measured. The field effect mobility calculated from the electrical characteristics was 33.5 cm²/Vs. It is confirmed that when the Poly-OS film is used as a channel of a thin film transistor, a field effect mobility (field effect mobility in a saturated region) greater than 30 cm²/Vs can be obtained.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each of the embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A thin film transistor, comprising:
a metal oxide layer provided over a substrate;
an oxide semiconductor layer comprising a plurality of crystal grains, provided in contact with the metal oxide layer;
a gate electrode provided over the oxide semiconductor layer; and
a gate insulating layer provided between the oxide semiconductor layer and the gate electrode,
wherein when a crystal orientation at each of a plurality of measurement points of the oxide semiconductor layer is obtained based on an electron diffraction pattern obtained by transmitting an electron beam irradiated from a direction intersecting a thickness direction of the oxide semiconductor layer, an average KAM value calculated at the plurality of measurement points is greater than or equal to 0.6 degrees.

2. The thin film transistor according to claim 1,
wherein the electron diffraction pattern at each of the plurality of measurement points is observed at a predetermined step interval, and
wherein the predetermined step interval is greater than or equal to 1 nm.

3. The thin film transistor according to claim 2, wherein the predetermined step interval is less than or equal to ⅕ of a thickness of the oxide semiconductor layer.

4. The thin film transistor according to claim 3, wherein the average KAM value increases as the predetermined step interval increases.

5. The thin film transistor according to claim 1, wherein at least one of two crystal grains adjacent to each other across a grain boundary forms a part of an upper surface and a part of a lower surface of the oxide semiconductor layer.

6. The thin film transistor according to claim 1, wherein a gap between two adjacent measurement points is defined as a grain boundary when the crystal orientation difference between the two adjacent measurement points exceeds 5 degrees.

7. The thin film transistor according to claim 1,
wherein two adjacent crystal grains with a grain boundary interposed therebetween overlap each other in the thickness direction of the oxide semiconductor layer, and
wherein an overlapping distance between the two adjacent crystal grains in the direction intersecting the thickness direction of the oxide semiconductor layer is greater than or equal to 10 nm.

8. The thin film transistor according to claim 7, wherein a gap between two adjacent measurement points is defined as a grain boundary when the crystal orientation difference between the two adjacent measurement points exceeds 5 degrees.

9. The thin film transistor according to claim 1, wherein a depth average value of KAM values at each of an upper end portion and a lower end portion of the oxide semiconductor layer is greater than or equal to 0.6 degrees.

10. The thin film transistor according to claim 1, wherein a difference between a depth average of KAM values at an upper end portion or a lower end portion of the oxide semiconductor layer and a depth average of KAM values at a central portion of the oxide semiconductor layer is greater than or equal to 0.1 degrees.

11. The thin film transistor according to claim 1, wherein in the thickness direction of the oxide semiconductor layer, a proportion of a crystal orientation <111> is larger than proportions of a crystal orientation <001> and a crystal orientation <101>.

12. The thin film transistor according to claim 1, wherein at least one of the plurality of crystal grains has a crystal grain length greater than or equal to 100 nm in the direction intersecting the thickness direction of the oxide semiconductor layer.

13. The thin film transistor according to claim 1,
wherein the oxide semiconductor layer comprises:
indium, and
at least one or more metal elements other than indium, and
wherein a ratio of the indium to the indium and the at least one or more metal elements is greater than or equal to 50%.

14. The thin film transistor according to claim 1, wherein a band gap of a metal oxide contained in the metal oxide layer is greater than or equal to 4 eV.

15. The thin film transistor according to claim 1, wherein the metal oxide layer comprises one or more metal elements selected from aluminum, magnesium, calcium, scandium, gallium, germanium, strontium, nickel, tantalum, yttrium, zirconium, barium, hafnium, cobalt, and lanthanoid elements.

16. The thin film transistor according to claim 1, wherein a crystal structure of the oxide semiconductor layer is a bixbyite structure.

17. An electronic device comprising the thin film transistor according to claim 1.
